(19) United States
(12) Patent Application Publication
(10) Pub. No.: US 2024/0204733 A1
(43) Pub. Date: Jun. 20, 2024

(54) AMPLIFIER CORE AND AMPLIFIER

(71) Applicant: POSTECH RESEARCH AND BUSINESS DEVELOPMENT FOUNDATION, Pohang-si (KR)

(72) Inventors: Ho-Jin SONG, Pohang-si (KR); Ji Seul KIM, Pohang-si (KR)

(73) Assignee: POSTECH RESEARCH AND BUSINESS DEVELOPMENT FOUNDATION, Pohang-si (KR)

(21) Appl. No.: 18/381,327

(22) Filed: Oct. 18, 2023

(30) Foreign Application Priority Data
Dec. 19, 2022 (KR) 10-2022-0178744

(51) Int. Cl. H03F 1/32; H03F 3/45

(52) U.S. Cl. CPC H03F 1/3211; H03F 3/45179; H03F 2200/451

(57) ABSTRACT

Proposed is an amplifier core which: includes an MOS transistor, and a T reactance network connected between input and output of the MOS transistor, wherein the amplifier core has two gain peaks spaced apart from each other.

### CROSS REFERENCE TO RELATED APPLICATION

The present application claims priority to Korean Patent Application No. 10-2022-0178744, filed Dec. 19, 2022, the entire contents of which are incorporated herein for all purposes by this reference.

### BACKGROUND OF THE INVENTION

### Field of the Invention

The present disclosure relates generally to an amplifier core and an amplifier.

### Description of the Related Art

Recently, millimeter wave (mm-wave) and sub-terahertz (sub-THz) frequencies have been receiving great attention in 6th generation (6G) mobile communications. An inherent wide bandwidth is an essential resource for high-capacity channels for high-speed communication. However, CMOS devices of THz transceivers do not have sufficient inherent power gain. To overcome this performance limitation, the concept of maximum achievable gain (Gmax) through a linear, lossless, and reciprocal (LLR) network has been studied. When some conditions are met, CMOS transistors can provide gains as high as Gmax, which is greater than their inherent maximum available gain (MAG) or unidirectional gain (U).

### SUMMARY OF THE INVENTION

The prior art generally used an inductor or inductive transmission line as an LLR network for a gain boosting amplifier based on a Gmax-core. However, this LLR communication device can provide a peak gain only at a single frequency, so a gain bandwidth is not wide enough.

In order to achieve the above objective, according to one aspect of the present disclosure, there is provided an amplifier core including: an MOS transistor, and a T reactance network connected between input and output of the MOS transistor, wherein the amplifier core has two gain peaks spaced apart from each other.

According to an aspect of the present embodiment, in the amplifier core, a two-port network may be formed, a gate of the MOS transistor and a source of the MOS transistor may respectively be ports on a primary side, and a drain of the MOS transistor and a source of the MOS transistor may respectively be ports on a secondary side.

According to an aspect of the present embodiment, the T reactance network may include: a first capacitor having a first electrode connected to the input of the MOS transistor and have a second electrode connected to a central node; a second capacitor having a first electrode connected to the output of the MOS transistor and having a second electrode connected to the central node; and an inductor having a first electrode connected to the central node and having a second electrode connected to a reference voltage.

According to an aspect of the present embodiment, the MOS transistor may be an NMOS transistor.

According to an aspect of the present embodiment, the amplifier core may have wideband gain characteristics between the two gain peaks.

According to an aspect of the present embodiment, the amplifier core may operate losslessly, linearly, and reciprocally.

According to the present embodiment, there is provided an amplifier, wherein the amplifier as a wideband amplifier includes: MOS transistors; T reactance networks, with each of the T reactance networks being connected between input and output of each of the MOS transistors; unit amplifiers, with each of the unit amplifiers including an amplifier core having two gain peaks spaced apart from each other; and an impedance matching circuit configured to connect the unit amplifiers to each other.

According to an aspect of the present embodiment, in the amplifier core, a two-port network may be formed, a gate of the MOS transistor and a source of the MOS transistor may respectively be ports on a primary side, and a drain of the MOS transistor and a source of the MOS transistor may respectively be ports on a secondary side.

According to an aspect of the present embodiment, the T reactance network may include: the first capacitor having a first electrode connected to the input of the MOS transistor and having a second electrode connected to the central node; the second capacitor having a first electrode connected to the output of the MOS transistor and having a second electrode connected to the central node; and the inductor having a first electrode connected to the central node and having a second electrode connected to the reference voltage.

According to an aspect of the present embodiment, in each of the unit amplifiers, two amplifier cores may form a differential pair.

According to an aspect of the present embodiment, each of the unit amplifiers may have wideband gain characteristics, and the amplifier may have wideband gain characteristics in a band including bands of the unit amplifiers.

According to an aspect of the present embodiment, the impedance matching circuit may include: a transformer; an inductor connected in series to a primary side of the transformer; and an inductor connected in series to a secondary side of the transformer.

According to the present embodiment, an amplifier that provides gain in a wide band is provided.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic circuit diagram illustrating the outline of an amplifier core according to the present embodiment;

FIG. 2 is a diagram illustrating double peak characteristic calculation;

FIG. 3 is a diagram illustrating maximum amplitude peaks and frequencies ω1 and ω2 at that time;

FIG. 4A is a schematic diagram illustrating the outline of an amplifier in which three cores of the present embodiment are connected to each other in a cascade, and FIG. 4B is a diagram schematically illustrating wideband gain characteristics of the amplifier in which three cores of the present embodiment are connected to each other in a cascade;

FIG. 5 is an exemplary circuit diagram of an amplifier in which unit differential amplifiers including cores according to the present embodiment are cascaded;

FIG. 6A is a diagram illustrating a maximum gain for frequency of an amplifier formed by cascading cores with two peak gains, and FIG. 6B is a diagram illustrating the simulated transimpedance of a matching circuit between a first stage and a second stage;

FIGS. 7A and 7B are diagrams illustrating an example of implementing a D-band amplifier according to the present embodiment; and

FIG. 8 is a diagram illustrating measurement results for the present embodiment.

### DETAILED DESCRIPTION OF THE INVENTION

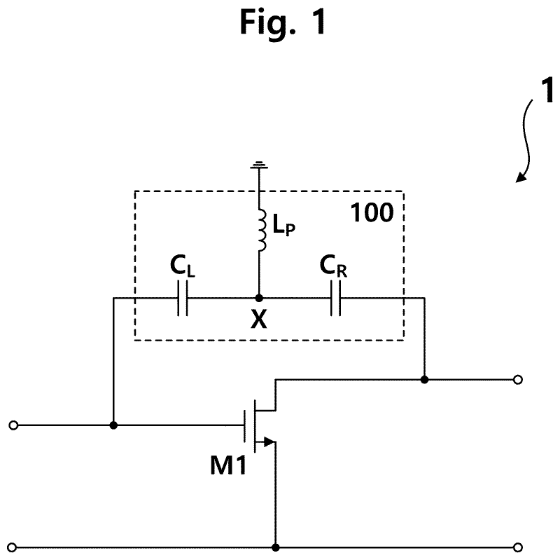

Hereinafter, the present embodiment will be described with reference to the accompanying drawings. FIG. 1 is a schematic circuit diagram illustrating the outline of an amplifier core 1 according to the present embodiment. Referring to FIG. 1, the amplifier core 1 includes an MOS transistor M1 and a T reactance network 100 connected between input and output of the MOS transistor M1, with the amplifier core 1 having two gain peaks spaced apart from each other and wideband gain characteristics between the two gain peaks.

In one embodiment, the T reactance network 100 may be wired in a T shape and connected between the input, output and reference voltage of the MOS transistor M1. For example, the T reactance network 100 includes: a first capacitor C1 having a first electrode connected to the input of the MOS transistor M1 and a second electrode connected to a central node X; a second capacitor C2 having a first electrode connected to the output of the MOS transistor M1 and a second electrode connected to the central node X; and an inductor L having a first electrode connected to the central node X and a second electrode connected to the reference voltage.

The present embodiment may be represented as an active 2-port system, and any active 2-port system is required to satisfy two conditions indicated by Equation 1 below for gain boosting.

$$cos ( arg ( \frac{{Y}_{21}}{{y}_{12}} ) ) = - 1 … , k = 1 … , \qquad [ Equation 1 ]$$

### (k: A Stability Factor, Y: A Y-Parameter of an Active 2-Port System)

At this time, Equation 1 related to the stability factor can be rewritten as Equation 2 below.

$$\frac{1}{4} + Re ( \frac{U \times {Y}_{12}}{{Y}_{21}} ) = {( Im ( \frac{U \times {Y}_{12}}{{Y}_{21}} ) )}^{2} \qquad [ Equation 2 ]$$

### (U: Unilateral Gain)

Since the network is a reversible network and is lossless, Y₁₂, a component of a Y parameter of an active two-port system, may be expressed as jBp, a susceptance matrix component. Accordingly, by dividing (U×Y₁₂)/(Y₂₁) of Equation 2 by the components of the T reactance network 100 and the MOS transistor M1, Equation 3 below may be expressed.

$$( \frac{U \times {Y}_{12}}{{Y}_{21}} ) \approx ( \frac{U \times {Y}_{12}^{mos}}{{Y}_{21}^{mos}} ) + j ( \frac{U \times B}{{Y}_{21}^{mos}} ) \qquad [ Equation 3 ]$$

### (Y: A Y-Parameter of an Active 2-Port System, U: Unilateral Gain, Bp: A Susceptance Matrix Element)

When Equation 2 and Equation 3 are organized into susceptance matrix components of the T reactance network 100, they yield Equation 4 below.

$${B}_{p 1} = \frac{- b + \sqrt{{b}^{2} - 4 a c}}{2 a} \qquad [ Equation 4 ]$$

$${B}_{p 1} = \frac{- b - \sqrt{{b}^{2} - 4 a c}}{2 a}$$

$$a = {( Re ( \frac{U}{{Y}_{21}^{mos}} ) )}^{2}$$

$$b = 2 \times Im ( \frac{{UY}_{12}^{mos}}{{Y}_{21}^{mos}} ) \times Re ( \frac{U}{{Y}_{21}^{mos}} ) + Im ( \frac{U}{{Y}_{21}^{mos}} )$$

$$c = {( Im ( \frac{{UY}_{12}^{mos}}{{Y}_{21}^{mos}} ) )}^{2} - ( 0.25 + Re ( \frac{{UY}_{12}^{mos}}{{Y}_{21}^{mos}} ) )$$

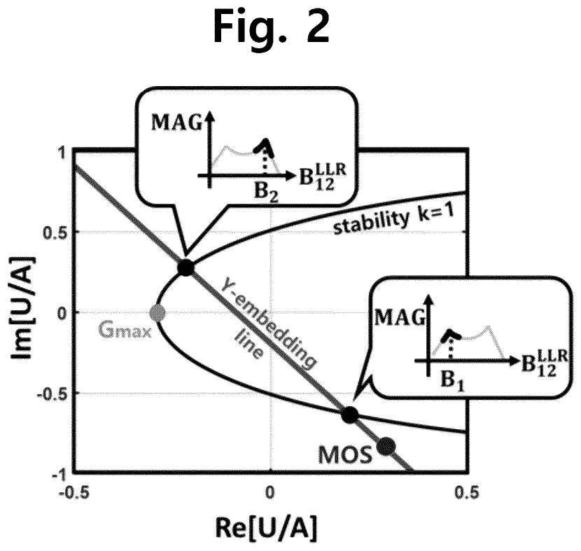

That is, when Bp1 and Bp2 of Equation 4 are satisfied at different frequencies ω1 and ω2, the active two-port amplification network 1 of the present embodiment has double peak characteristics as illustrated in FIG. 2.

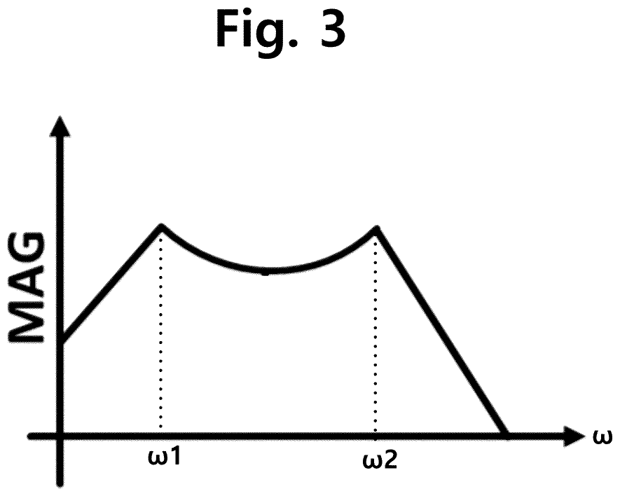

FIG. 2 is a diagram illustrating double peak characteristic calculation. Referring to FIG. 2, a parabola marked in black is a graph of a stability factor k=1 represented as in Equation 2. In addition, the T reactance network 100 and the MOS transistor M1 may be shown as a diagram of a red line in FIG. 2, and the intersection points of the parabola and the red line are values of Bp1 and Bp2 that are required to be satisfied at frequencies ω1 and ω2 that form maximum amplitude peaks illustrated in FIG. 3.

When the T reactance network 100 that satisfies the frequencies ω1 and ω2 illustrated in FIGS. 2 and 3 is expressed as each component, the T reactance network 100 can be calculated as in Equation 5 below.

$$\frac{1}{{C}_{L}} + \frac{1}{{C}_{R}} = \frac{{B}_{p 1} {w}_{2}^{3} - {B}_{p 2} {w}_{1}^{3}}{{B}_{p 1} {B}_{p 2} ( {w}_{1}^{2} - {w}_{2}^{2} )} \qquad [ Equation 5 ]$$

$$\frac{1}{{L}_{p}} = {C}_{L} {C}_{R} ( \frac{{w}_{1}^{3}}{{B}_{p 1}} + \frac{{w}_{1}^{2}}{{C}_{L}} + \frac{{w}_{1}^{2}}{{C}_{R}} )$$

Therefore, it is possible to form an amplifier core with high gain between target frequencies, ω1 and ω2.

Y parameters of the T reactance network 100 are as shown in Equation 6 below.

$${B}_{11}^{T} = \frac{ω {C}_{L} ( {ω}^{2} {C}_{R} {L}_{P} - 1 )}{{ω}^{2} {C}_{L} {L}_{P} + {ω}^{2} {C}_{R} {L}_{P} - 1} \qquad [ Equation 6 ]$$

$${B}_{22}^{T} = \frac{ω {C}_{R} ( {ω}^{2} {C}_{L} {L}_{P} - 1 )}{{ω}^{2} {C}_{L} {L}_{P} + {ω}^{2} {C}_{R} {L}_{P} - 1}$$

$${B}_{12}^{T} = {B}_{21}^{T} = {B}_{pT}$$

From this, the input admittance (Yin) and output admittance (Yout) of the amplifier core of the present embodiment are calculated as Equation 7 below.

$${Y}_{i n} = {Y}_{11}^{mos} + {jB}_{11}^{T} - \frac{( {Y}_{21}^{mos} + {jB}_{p T} ) ( {Y}_{12}^{mos} + {jB}_{pT} )}{{Y}_{22}^{mos} + {jB}_{22}^{T} + {Y}_{0}} \qquad [ Equation 7 ]$$

$${Y}_{ou t} = {Y}_{22}^{mos} + {jB}_{22}^{T} - \frac{( {Y}_{21}^{mos} + {jB}_{pT} ) ( {Y}_{12}^{mos} + j {B}_{pT} )}{{Y}_{11}^{mos} + {jB}_{11}^{T} + {Y}_{0}}$$

From this, as will be described later, when connecting a plurality of cores in a cascade to form the amplifier 100, impedance matching can be easily performed by adjusting a Q value viewed from a primary side of a transformer and a Q value viewed from a secondary side thereof.

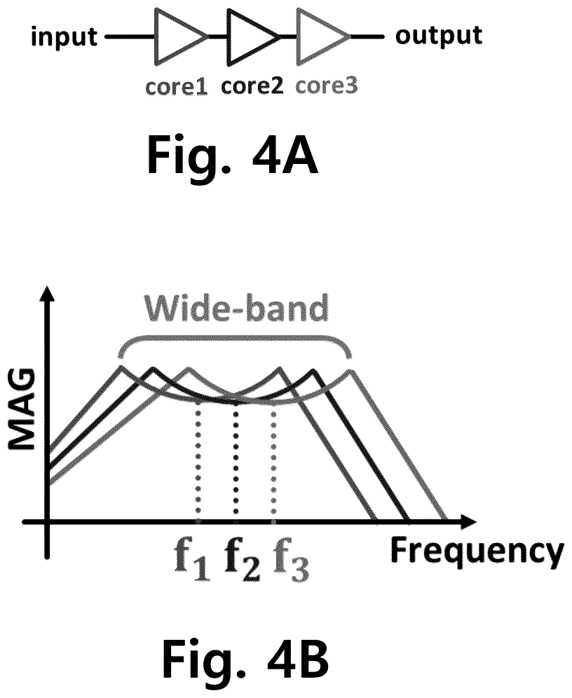

FIG. 4A is a schematic diagram illustrating the outline of the amplifier 100 in which three cores of the present embodiment are connected to each other in a cascade, and FIG. 4B is a diagram schematically illustrating wideband gain characteristics of the amplifier 100 in which three cores of the present embodiment are connected to each other in a cascade. In the prior art, there was an attempt to improve widedband gain characteristics by cascading unit amplifier cores. However, since each of the unit cores had narrowband characteristics, an amplifier formed by cascading the cores could not achieve excellent wideband gain characteristics.

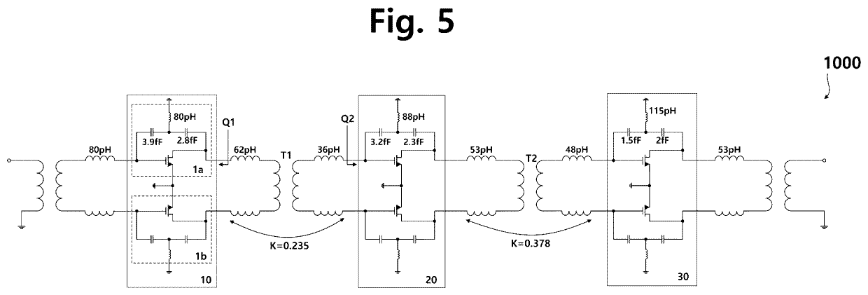

However, according to the present embodiment illustrated in FIG. 4A, each of cores with high gain in a wide frequency band is cascaded to form an amplifier. Accordingly, as illustrated in FIG. 4B, the amplifier of the present disclosure can obtain good gain characteristics in a wide frequency range. FIG. 5 is an exemplary circuit diagram of an amplifier 1000 in which unit differential amplifiers 10, 20, and 30 including cores 1a and 1b according to the present embodiment are cascaded. Referring to FIG. 5, the cores of the present embodiment are illustrated as dotted boxes, and are combined to form differential pairs. The source of an MOS transistor included in each of the cores forms a virtual ground.

The differential pairs formed by combining each of the cores 1a and 1b form the unit differential amplifiers 10, 20, and 30, and the unit differential amplifiers 10, 20, and 30 are combined with each other in a cascade through the transformers T1 and T2 so as to perform impedance matching.

Inductors are respectively connected in series to the primary and secondary sides of the transformers T1 and T2. The coupling coefficients K of the transformers are adjusted by inductance of the inductors connected in series to the primary and secondary sides. The transformers T1 and T2 are set up to handle all six gain peaks formed by three cores connected in a cascade. In one embodiment, the element value of the T reactance network can be determined so that Q1, which is a quality factor Q viewed from the primary side of the transformer T1, and Q2, which is a quality factor viewed from the secondary side thereof, correspond to each other. From this, impedance matching is performed so that maximum power is transferred.

In the prior art, shunt capacitors connected between input and output were connected to perform impedance matching. Therefore, since capacitors for impedance matching are essential, an area required to form a circuit has increased, which increased manufacturing costs. However, in the present embodiment, the element value of the T reactance network is determined between the primary and secondary sides of the transformer and impedance matching is performed according to a Q value, so a shunt capacitor is unnecessary, which provides the advantage of being economical.

### Examples of Experiment and Simulation

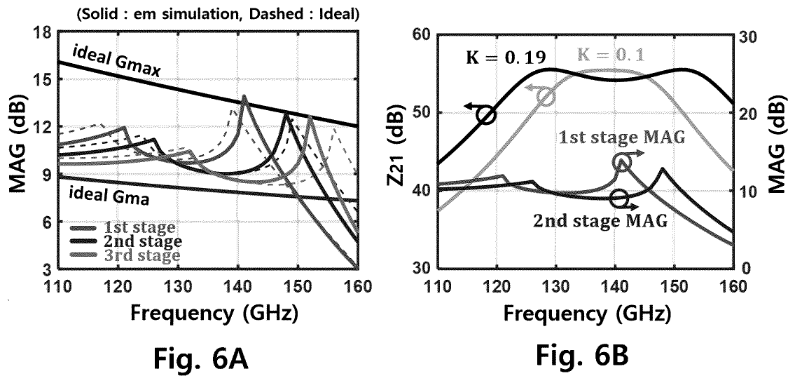

FIG. 6A is a diagram illustrating a maximum gain for frequency of an amplifier formed by cascading cores with two peak gains, and FIG. 6B is a diagram illustrating the simulated transimpedance of a matching circuit between a first stage and a second stage. The amplifier was implemented as a wideband amplifier by connecting three cores in a cascade, as illustrated in FIG. 5.

A gain peak frequency is set according to a target gain bandwidth, and from this, values of CL, CR, and LP included in each core are determined. As illustrated in FIG. 6A, a maximum gain peak (MAG) occurs in a range of 110-150 GHz. It is designed to have a higher maximum gain for the second peak at higher frequencies to compensate for losses at the higher frequency edges. In addition, it can be seen that the amplifier of the present embodiment provides gain in a band that includes all bands of unit amplifiers, and that the amplifier provides high gain in a wide band that includes the lowest to the highest frequencies among the bands of the unit amplifiers.

In addition, in relation to the setting of the input and output capacitances of each core, the input/output capacitances are required to be independent of frequencies and are designed not to form an additional capacitor to be suitable for a transformer-based matching circuit for a 4th order transimpedance filter.

Referring to FIG. 6B, as described above, an impedance matching circuit includes a transformer, and an inductor connected in series to each of the primary and secondary sides of the transformer sets the coupling coefficient K of the transformer. Accordingly, the bandwidth of the impedance matching circuit can handle all six gain peaks.

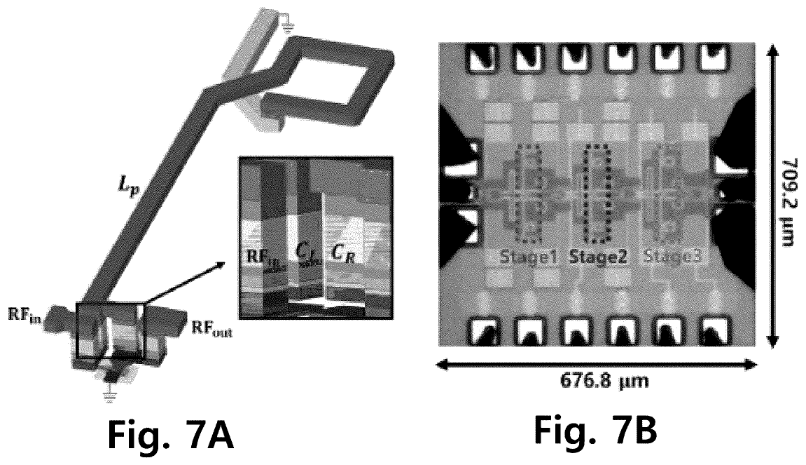

FIGS. 7A and 7B illustrate an example of implementing a D-band amplifier according to the present embodiment. The amplifier is formed in a 28 nm FD-SOI CMOS process.

Small-signal s-parameters were measured with a VNA and WR-6.5 frequency expander, and the input expander includes an attenuator that can provide input power of about −35 dBm. FIG. 8 illustrates measurement results for the present embodiment. The amplifier was measured to have power gains of 14.5 dB and 26 GHz (117-143 GHZ) and 3 dB bandwidth, respectively, with a power loss of 21.6 mW·Hz).

Table 1 below summarizes the measured performance of the presented wideband amplifier and a recently reported similar frequency band amplifier. It can be seen that despite the slightly lower fmax of the core transistor, the proposed amplifier has improved performance in terms of a normalized gain-bandwidth product per DC loss.

TABLE 1

| | embodiment | prior art 1 | prior art 2 | prior art 3 | prior art 4 | prior art 5 |
|---|---|---|---|---|---|---|
| Technology | 28-nm FDSOI | 28-nm FDSOI | 28-nm CMOS | 45-nm CMOS | 28-nm FDSOI | 45-nm CMOS |
| fₘₐₓ (GHz) | 291 | 390 | 410 | — | 430 | — |
| Core | 3-CS | 1-CS | 5-CS | 4-CS | 4-CS | 4-CS |
| topology | Gain-boosting | Gain-boosting | Gain-boosting | neutralization | — | neutralization |
| | (T-shaped FB) | (TL FB) | (Mosfet FB) | | | |
| Matching | Wideband | TL Stub | Transformer | Transformer | Wideband | Transformer |
| topology | Transformer | | | | CS-CPW | |
| f_{center} (GHz) | 130 | 184 | 192.8 | 152.5 | 154.5 | 141 |
| Gain (AB) | 14.5 | 7.6 | 14.3 | 18 | 15.7 | 16 |
| 3 dB Banwidth | 26 (20%) | 20 (10.9%) | 14.4 (7.5%) | 17.5 (11.5%) | 23 (14.9%) | 31.5 (22.3%) |
| (GHz) | | | | | | |
| DC power (mW) | 21.6 | 5.1 | 45 | 92 | 32 | 75 |
| Core area (mm²) | 0.1 | 0.1^{#} | 0.09 | 0.04 | 0.34 | 0.07 |
| FOM₁* | 34 | 23 | 9 | 12 | 27 | 17 |
| FOM₂** | 733 | 115 | 388 | 1104 | 855 | 1266 |

A gain boosting core according to the present embodiment provides two maximum gain peaks at different frequencies that can be designed independently, and thus can implement a wide gain bandwidth with fewer stages than existing technologies. In addition, the input and output impedance of a proposed A2P can be adjusted, thereby providing a high degree of freedom in designing a high-gain and wideband amplifier.

Although the present invention has been described with reference to the embodiment illustrated in the drawings to aid understanding, this is an embodiment for implementation and are merely illustrative, and it will be understood that those skilled in the art may make various modifications and implement other equivalent embodiments. Accordingly, the scope of technical protection of the present disclosure should be determined by the appended claims.

What is claimed is:

1. An amplifier core comprising:
an MOS transistor, and
a T reactance network connected between input and output of the MOS transistor,
wherein the amplifier core has two gain peaks spaced apart from each other.

2. The amplifier core of claim 1, wherein a two-port network is formed,
a gate of the MOS transistor and a source of the MOS transistor respectively are ports on a primary side, and
a drain of the MOS transistor and a source of the MOS transistor respectively are ports on a secondary side.

3. The amplifier core of claim 1, wherein the T reactance network comprises:
a first capacitor having a first electrode connected to the input of the MOS transistor and have a second electrode connected to a central node;
a second capacitor having a first electrode connected to the output of the MOS transistor and having a second electrode connected to the central node; and
an inductor having a first electrode connected to the central node and having a second electrode connected to a reference voltage.

4. The amplifier core of claim 1, wherein the MOS transistor is an NMOS transistor.

5. The amplifier core of claim 1, wherein the amplifier core has wideband gain characteristics between the two gain peaks.

6. The amplifier core of claim 1, wherein the amplifier core operates losslessly, linearly, and reciprocally.

7. An amplifier, wherein the amplifier as a wideband amplifier comprises:
MOS transistors;
T reactance networks, with each of the T reactance networks being connected between input and output of each of the MOS transistors;
unit amplifiers, with each of the unit amplifiers comprising an amplifier core having two gain peaks spaced apart from each other; and
an impedance matching circuit configured to connect the unit amplifiers to each other.

8. The amplifier of claim 7, wherein in the amplifier core, a two-port network is formed,
a gate of the MOS transistor and a source of the MOS transistor respectively are ports on a primary side, and
a drain of the MOS transistor and a source of the MOS transistor respectively are ports on a secondary side.

9. The amplifier of claim 7, wherein the T reactance network comprises:
a first capacitor having a first electrode connected to the input of the MOS transistor and having a second electrode connected to a central node;
a second capacitor having a first electrode connected to the output of the MOS transistor and having a second electrode connected to the central node; and
an inductor having a first electrode connected to the central node and having a second electrode connected to a reference voltage.

10. The amplifier of claim 7, wherein in each of the unit amplifiers, two amplifier cores form a differential pair.

11. The amplifier of claim 7, wherein each of the unit amplifiers has wideband gain characteristics, and
the amplifier has wideband gain characteristics in a band comprising bands of the unit amplifiers.

12. The amplifier of claim 7, wherein the impedance matching circuit comprises:
a transformer;
an inductor connected in series to a primary side of the transformer; and
an inductor connected in series to a secondary side of the transformer.
